(19) United States
(12) Patent Application Publication
(10) Pub. No.: US 2010/0224927 A1
(43) Pub. Date: Sep. 9, 2010

(54) NONVOLATILE SEMICONDUCTOR MEMORY DEVICE

(75) Inventors: Takamitsu Ishihara, Kanagawa (JP); Daisuke Hagishima, Kanagawa (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/714,817

(22) Filed: Mar. 1, 2010

(30) Foreign Application Priority Data
Mar. 4, 2009 (JP) 2009-050027

(51) Int. Cl. H01L 29/792

(52) U.S. Cl. 257/324; 257/E29.309

(57) ABSTRACT

A NAND-type nonvolatile semiconductor memory device which suppresses write error caused by hot carriers and has improved reliability is provided. On a main plane of a semiconductor substrate, a plurality of memory cell transistors connected in series with each other, and a select gate transistor connected to an end of the plurality of memory cell transistors are arranged. A first impurity layer of a conductivity type opposite to that of the substrate is formed as a common source/drain on the semiconductor substrate between the select gate transistor and the memory cell transistor connected thereto. An impurity concentration distribution of the first impurity layer is asymmetrical with respect to a first virtual plane being at equal distances from ends of the select gate electrode and the control gate electrode and being perpendicular to the main plane, and an impurity concentration of the first impurity layer on the memory cell transistor side is higher than that on the gate transistor side with reference to the first virtual plane.

### CROSS-REFERENCE TO RELATED APPLICATION

This application is based upon and claims the benefit of priority from Japanese Patent Application No. 2009-050027, filed on Mar. 4, 2009, the entire contents of which are incorporated herein by reference.

### TECHNOLOGY FIELD

Exemplary embodiments described herein relates to a NAND-type nonvolatile semiconductor memory device.

### BACKGROUND

In recent years, with rapid expansion of the markets for recording media represented by digital cameras and mobile audio devices represented by mobile phones, the demand for NAND-type flash memories has rapidly grown. At the present, in order to realize small size, light weight, and multifunctionality of these devices, flash memories are increasingly down-sized, high integrated, and reduced in power supply voltages.

A NAND-type flash memory is obtained by connecting a plurality of MOS-type nonvolatile semiconductor memory devices in series with each other. As is well known, one of the devices includes a source/drain diffusion layer formed on a semiconductor substrate surface, a gate insulating film stacked on the semiconductor substrate between the source/drain diffusion layer, a floating gate, an inter-gate insulating film, and a control gate electrode (for example, JP2007-66355 (KOKAI)).

However, with the development of scaled-down flash memories, degradation in reliability has become a problem. In a memory cell portion of a scaled-down NAND-type flash memory where a write/erase operation is actually performed, a high electric field locally occurs in the device. Due to this high electric field, hot carriers are generated. The hot carriers degrade the reliability of the device.

With an advance of scaling down, a distance between transistors decreases. Due to this, it is predicted that electric field concentration in a device becomes increasingly conspicuous, resulting in a risk of increase in the reliability degradation. As long as a NAND-type flash memory of the conventional structure is supposed, the problem becomes more serious with progress of generation of the memory.

### SUMMARY

A nonvolatile semiconductor memory device according to a first aspect of the present invention includes a semiconductor substrate; a plurality of memory cell transistors placed in series with each other formed on a plain of the semiconductor substrate, each of the memory cell transistors includes a first insulating film on the semiconductor substrate, a charge storage layer on the first insulating film, a second insulating film on the charge storage layer, and a control gate electrode on the second insulating film; and a select gate transistor placed an end of the plurality of memory cell transistors, the select gate transistor includes a third insulating film on the semiconductor substrate, and a select gate electrode on the third insulating film, wherein a first impurity layer of a conductivity type opposite to the conductivity type of the semiconductor substrate is formed as a common source/drain on the semiconductor substrate between the select gate transistor and the memory cell transistor next to the select gate transistor, an impurity concentration distribution of the first impurity layer is asymmetrical with respect to a first virtual plane being at equal distances from ends of the select gate electrode and the control gate electrode and being perpendicular to the plane, and an impurity concentration of the first impurity layer on the memory cell transistor side is higher than that on the select gate electrode side.

A nonvolatile semiconductor memory device according to a second aspect of the present invention includes a semiconductor substrate; a plurality of memory cell transistors placed in series with each other formed on a plain of the semiconductor substrate, each of the memory cell transistors includes a first insulating film on the semiconductor substrate, a first charge storage layer on the first insulating film, a second insulating film on the first charge storage layer, and a control gate electrode on the second insulating film; a dummy cell transistor placed an end of the plurality of memory cell transistors, the dummy cell transistor includes a fourth insulating film on the semiconductor substrate, a second charge storage layer on the fourth insulating film, a fifth insulating film on the second charge storage layer, and a dummy gate electrode on the fifth insulating film; and a select gate transistor placed next to the dummy cell transistor, the select gate transistor includes a third insulating film on the semiconductor substrate, and a select gate electrode on the third insulating film, wherein a first impurity layer of a conductivity type opposite to the conductivity type of the semiconductor substrate is formed as a common source/drain on the semiconductor substrate between the select gate transistor and the dummy cell transistor next to the select gate transistor, an impurity concentration distribution of the first impurity layer is asymmetrical with respect to a first virtual plane being at equal distances from ends of the select gate electrode and the dummy gate electrode and being perpendicular to the plane, and an impurity concentration of the first impurity layer on the dummy cell transistor side is higher than that on the select gate electrode side.

A nonvolatile semiconductor memory device according to a third aspect of the present invention includes a semiconductor substrate; a plurality of memory cell transistors placed in series with each other formed on a plain of the semiconductor substrate, each of the memory cell transistors includes a first insulating film on the semiconductor substrate, a charge storage layer on the first insulating film, a second insulating film on the charge storage layer, and a control gate electrode on the second insulating film; and a select gate transistor placed an end of the plurality of memory cell transistors, the select gate transistor includes a third insulating film on the semiconductor substrate and a select gate electrode on the third insulating film, wherein a conductive layer containing a metal is formed as a common source/drain on the semiconductor substrate between the select gate transistor and the memory cell transistor next to the select gate transistor, and a horizontal distance between the conductive layer and the select gate electrode is larger than a horizontal distance between the conductive layer and the control gate electrode.

A nonvolatile semiconductor memory device according to a fourth aspect of the present invention includes a semiconductor substrate; a plurality of memory cell transistors placed in series with each other formed on a plain of the semiconductor substrate, each of the memory cell transistors includes a first insulating film on the semiconductor substrate, a first charge storage layer on the first insulating film, a second insulating film on the first charge storage layer, and a control gate electrode on the second insulating film; a dummy cell transistor placed an end of the plurality of memory cell transistors, the dummy cell transistor includes a fourth insulating film on the semiconductor substrate, a second charge storage layer on the fourth insulating film, a fifth insulating film on the second charge storage layer, and a dummy gate electrode on the fifth insulating film; and a select gate transistor placed next to the dummy cell transistor, the select gate transistor includes a third insulating film on the semiconductor substrate, and a select gate electrode on the third insulating film, wherein a conductive layer containing a metal is formed as a common source/drain on the semiconductor substrate between the select gate transistor and the dummy cell transistor next to the select gate transistor, and a horizontal distance between the conductive layer and the select gate electrode is larger than a horizontal distance between the conductive layer and the dummy gate electrode.

### BRIEF DESCRIPTION OF THE DRAWINGS

FIGS. 1A and 1B are sectional views of a nonvolatile semiconductor memory device according to a first embodiment.

FIG. 2 is a diagram showing an example of a voltage application pattern in a write state.

FIG. 3 is a sectional view in a gate length direction of a non-selected NAND string.

FIG. 4 is a diagram showing a simulation result of an electric field distribution.

FIG. 5 is a band diagram in a high electric field region.

FIG. 6 is a diagram showing a simulation result of a generation rate of electrons due to BBT.

FIG. 7 is a diagram showing a simulation result of an electron temperature distribution of thermal electrons.

FIG. 8 is a graph showing a distribution of As considered in the simulation.

FIG. 9 is a graph showing dependence of a threshold voltage shift on maximum impurity concentration of a diffusion layer.

FIG. 10 is a graph showing a surface potential distribution between a select gate and a memory cell transistor 0.

FIG. 11 is a graph showing a channel-direction electric field distribution.

FIG. 12 is a diagram showing an electric field distribution obtained when maximum impurity concentration of a diffusion layer is 5e18 cm⁻³.

FIG. 13 is a diagram showing an electric field distribution obtained when maximum impurity concentration of the diffusion layer is 3e18 cm⁻³.

FIG. 14 is a graph showing comparison of a diffusion layer impurity profile and a surface potential distribution of the first embodiment with those of a conventional technique.

FIG. 15 is a graph showing comparison of the diffusion layer impurity profile and a channel electric field of the first embodiment with those of a conventional technique.

FIGS. 16A and 16B are comparative diagrams of temperature distributions of thermal electrons of the first embodiment.

FIG. 17 is a graph showing comparison of a surface electron temperature distribution of thermal electrons of the first embodiment with that of a conventional technique.

FIG. 18 is a graph showing a thermal electron erroneous write suppression effect of the first embodiment.

FIGS. 19A to 19G are sectional views showing steps of a method of manufacturing the nonvolatile semiconductor memory device according to the first embodiment.

FIG. 20 is a sectional view of a main part of a nonvolatile semiconductor memory device according to a second embodiment.

FIGS. 21A to 21F are sectional views showing steps of a method of manufacturing the nonvolatile semiconductor memory device according to the second embodiment.

FIGS. 22A and 22B are sectional views of a nonvolatile semiconductor memory device according to a third embodiment.

FIGS. 23A and 23B are sectional views of a nonvolatile semiconductor memory device according to a fourth embodiment.

FIGS. 24A to 24G are sectional views showing steps of a method of manufacturing the nonvolatile semiconductor memory device according to the fourth embodiment.

FIGS. 25A and 25B are sectional views of a nonvolatile semiconductor memory device according to a fifth embodiment.

FIGS. 26A and 26B are sectional views of a nonvolatile semiconductor memory device according to a sixth embodiment.

### DETAILED DESCRIPTION OF THE EMBODIMENTS

Embodiments of the present invention will be described below with reference to the drawings. Throughout the embodiment, the same reference symbols denote the same configurations, and a description thereof will not be repeated. The drawings are schematic illustrations to help explanation and comprehension of the embodiment, and thus, shapes, sizes, proportions, and the like in the drawings may be different from those of the actual devices. The shapes, sizes, proportions and the like may be arbitrarily changed in design in consideration of the following explanation and known techniques.

In this specification, a “charge storage layer” means a layer which can store electric charges therein. More specifically, a “charge storage layer” which is included in a memory cell transistor means a layer having a feature of positively storing electric charges. On the other hand, a “charge storage layer” which is included in a dummy cell transistor does not have a feature of positively storing electric charges but can store electric charges that have entered into a layer as hot carriers in the layer. In the specification, a “semiconductor substrate” is a concept including a semiconductive substrate such as a bulk substrate or an SOI substrate used in manufacture of a semiconductor device. An “impurity layer of a conductivity type opposite to that of a semiconductor substrate” in a bulk substrate means an impurity layer having a conductivity type opposite to that of a bulk and a well on which a semiconductor device is formed. In an SOI substrate, the impurity layer means an impurity layer having a conductivity type opposite to that of a SOI layer on which a semiconductor device is formed.

### First Embodiment

A nonvolatile semiconductor memory device according to a first embodiment of the present invention includes on a main plane of a semiconductor substrate: a plurality of memory cell transistors connected in series with each other and select gate transistors connected to ends of the plurality of memory cell transistors. Each of the memory cell transistors includes a first insulating film on the semiconductor substrate, a charge storage layer on the first insulating film, a second insulating film on the charge storage layer, and a control gate electrode on the second insulating layer. Each of the select gate transistors includes a third insulating film on the semiconductor substrate, and a select gate electrode on the third insulating film. A first impurity layer of a conductivity type opposite to the conductivity type of the semiconductor substrate is formed as a common source/drain on the semiconductor substrate between each of the select gate transistors and the memory cell transistor connected to the select gate transistor. In this case, an impurity concentration distribution of the first impurity layer is asymmetrical with respect to a first virtual plane being at equal distances from ends of the select gate electrode and the control gate electrode and being perpendicular to the main plane of the semiconductor substrate, and an impurity concentration of the first impurity layer on the memory cell transistor side is higher than that on the select gate electrode side with reference to the first virtual plane. The semiconductor memory device according to the embodiment is a so-called NAND-type flash memory.

The nonvolatile semiconductor memory device according to the embodiment has the above-mentioned configuration, so that it can suppress write error due to hot carrier injection in memory cell transistors connected adjacent to the select gate transistors. Therefore, a NAND-type nonvolatile semiconductor memory device having improved reliability can be provided.

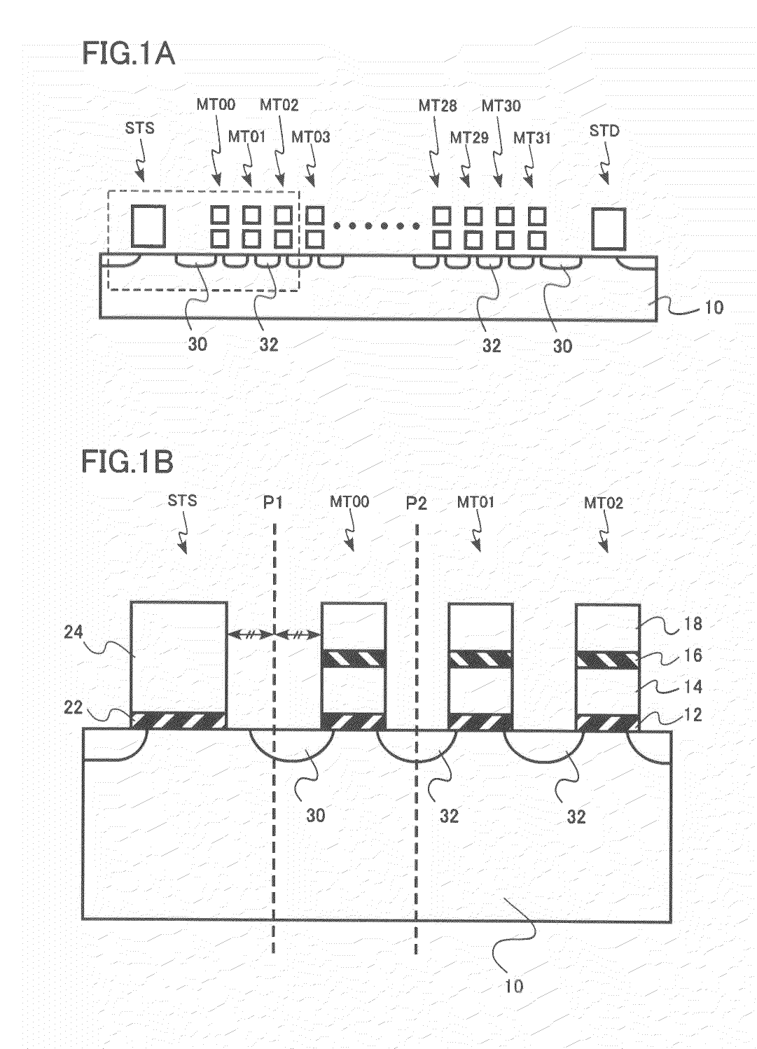

FIGS. 1A and 1B are sectional views of a nonvolatile semiconductor memory device according to the embodiment. FIG. 1A is an entire diagram, and FIG. 1B is an enlarged diagram of a main part indicated by a broken-line rectangle in FIG. 1A.

As shown in FIG. 1A, the nonvolatile semiconductor memory device according to the embodiment includes a plurality of memory cell transistors MT00 to MT31 connected in series with each other on a main plane of a semiconductor substrate 10. The semiconductor substrate 10 is, for example, a p-type silicon substrate.

Select gate transistors STS and STD are connected to ends of the plurality of memory cell transistors MT00 to MT31. In this case, the select gate transistor STS on a source side is connected to the memory cell transistor MT00, and the select gate transistor STD on a drain side, i.e., a bit line (BL) side is connected to the memory cell transistor MT31.

A structure in which the select gate transistor STS, the plurality of memory cell transistors MT00 to MT31, and the select gate transistor STD are connected in series with each other is called a NAND string.

Each of the memory cell transistors MT00 to MT31 includes a first insulating film 12 on the semiconductor substrate 10, a charge storage layer 14 on the first insulating film 12, a second insulating film 16 on the charge storage layer 14, and a control gate electrode 18 on the second insulating film 16 as shown in FIG. 1B. The first insulating film 12 is made of a silicon oxide film, for example. The charge storage layer 14 is made of, polysilicon, for example. The second insulating film 16 is made of alumina, for example. The control gate electrode 18 is formed to have a stacked structure of polysilicon and tantalum nitride, for example.

The charge storage layer 14 is a so-called floating gate electrode, and has a feature of positively or willingly storing electric charge as memory cell information. The first insulating film 12 works as an electron/hole transfer path between a channel region and the charge storage layer 14 in a write/erase state of the memory cell due to a tunneling phenomenon. In a read/standby state, the first insulating film 12 has a feature of suppressing electron/hole transfer between the channel region and the charge storage layer 14 due to the barrier height of the first insulating film 12. The second insulating film 16 is a so-called inter-electrode insulating film, and has a feature of blocking a flow of electrons and holes between the charge storage layer 14 and the control gate electrode 18.

Each of the select gate transistors STS and STD has a third insulating film 22 on the semiconductor substrate 10 and a select gate electrode 24 on the third insulating film 22. The third insulating film 22 is made of, for example, a silicon oxide film. The select gate electrode 24 is formed as a stacked film of, for example, polysilicon and tantalum nitride.

A first impurity layer 30 of a conductivity type opposite to that of the semiconductor substrate 10 is formed as a common source/drain on the semiconductor substrate 10 between each of the select gate transistors and the memory cell transistor connected to the select gate transistor. FIG. 1B shows the first impurity layer 30 formed between the select gate transistor STS on the source side and the memory cell transistor MT00. In this case, when the semiconductor substrate 10 is of a p-type, the first impurity layer 30 is, for example, an n-type As diffusion layer of an opposite conductivity type.

An impurity concentration distribution (or an impurity profile) of the first impurity layer 30 is asymmetrical with respect to a first virtual plane P1 being at equal distances from the ends of the select gate electrode 24 of the select gate transistor STS and the control gate electrode 18 of the memory cell transistor MT00 and being perpendicular to the main plane of the semiconductor substrate 10. Furthermore, an impurity concentration of the first impurity layer 30 on the memory cell transistor MT00 side is higher than that on the select gate transistor STS side with reference to the first virtual plane P1. Since the virtual plane P1 is a plane perpendicular to the plane of the drawing, the first virtual plane P1 is indicated by a broken straight line in FIG. 1B.

In the embodiment, the first impurity layer 30 has an offset spacing with respect to the select gate electrode 24 to obtain an asymmetrical concentration distribution.

Methods of evaluating asymmetry of the impurity concentration distribution and a magnitude of concentration are not limited. For example, an impurity distribution of the impurity layer can be measured three-dimensionally by using, for example, an atomic probe method. Alternatively, a plurality of positions in an impurity layer being at equal distances from the first virtual plane P1 on both the sides in the same sample can be analyzed and compared by SIMS (Secondary Ionization Mass Spectrometer) method. For example, when measurement in the same sample is difficult, positions in impurity layers being at equal distances from the virtual plane P1 on both the sides in a plurality of samples, for example, diffusion layers immediately under ends of gate electrodes may be measured to calculate averages, and then, the averages may be compared.

In the embodiment, the first impurity layer 30 between the select gate transistor STD on the drain side and the memory cell transistor MT31 also has the same structure as that of the first impurity layer 30 between the select gate transistor STS and the memory cell transistor MT00.

As shown in FIG. 1B, a second impurity layer 32 of a conductivity type opposite to that of the semiconductor substrate 10 is also formed as a common source/drain on the semiconductor substrate 10 between each two of the memory cell transistors connected with each other, in this case, the memory cell transistors MT00 and MT01 or the memory cell transistors MT01 and MT02. An impurity concentration distribution of the second impurity layer 32 is desirably symmetrical with respect to a second virtual plane P2 being at equal distances from the ends of the control gate electrodes 18 of the two memory cell transistors and being perpendicular to the main plane of the semiconductor substrate 10. This is because if the impurity concentration distribution of each of the second impurity layers 32 is asymmetrical, the characteristics of the memory cell transistors are asymmetrical causing a risk of inducing instability of a memory operation.

A write error suppression effect according to the embodiment will be described below. Write error caused by hot carrier in a NAND flash memory becomes a serious problem particularly in a non-selected NAND string.

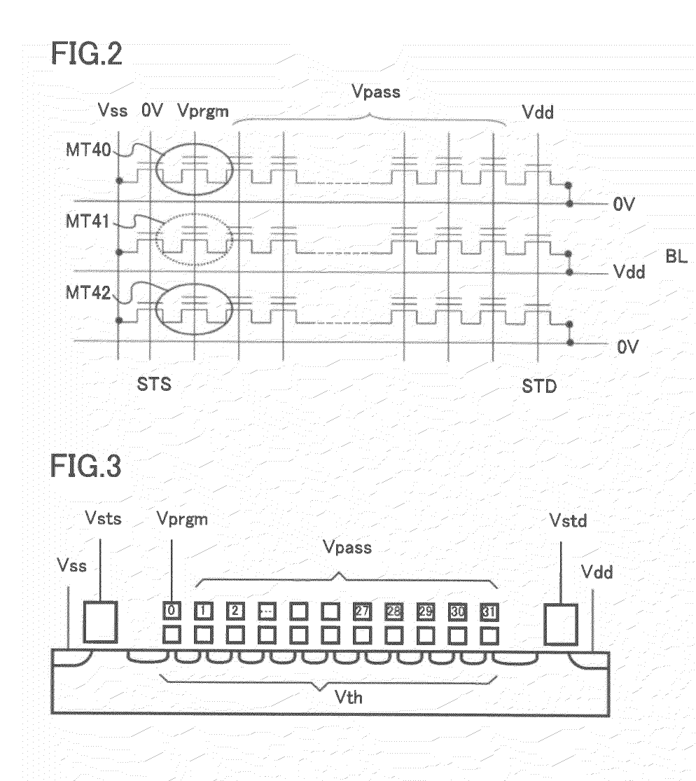

FIG. 2 is a diagram showing an example of a voltage application pattern in a write state. FIG. 2 shows an example of a voltage application pattern when electrons are written in memory cell transistors MT40 and MT42 connected to the select gate transistors.

A control gate voltage Vprgm is applied to the memory cell transistors MT40 and MT42. A voltage of 0 V and a voltage Vss are applied to gate electrodes and sources of the select gate transistors STS on the source side adjacent to these memory cell transistors, respectively. Voltage Vdd is applied to the gate electrodes of the select gate transistors STD on a BL (bit line) side and the BL, respectively. A voltage Vpass is applied to the control gate electrodes of memory cell transistors except for the memory cell transistors MT40, MT41, and MT42. The control gate voltage Vprgm is, for example, 20 V, the voltage Vss is, for example, 1.5 V, the voltage Vdd is, for example, 2.5 V, and the voltage Vpass is, for example, 8 V.

At this time, electrons are written in the charge storage layers 14 of the memory cell transistors MT40 and MT42. On the other hand, it is assumed that no electrons are written in the memory cell transistor MT41. A NAND string having the memory cell transistor MT41, which is assumed that no electrons are written, is called a non-selected NAND string.

FIG. 3 is a sectional view of a non-selected NAND string in a gate length direction. In FIG. 3, sequential numbers 0, 1, 2, . . . are provided to the memory cell transistors from the memory cell transistor on the source side.

As is apparent from FIGS. 2 and 3, the control gate voltage Vprgm is applied to the memory cell transistor 0 in FIG. 3. Originally, no electrons should be written in the memory cell transistor 0.

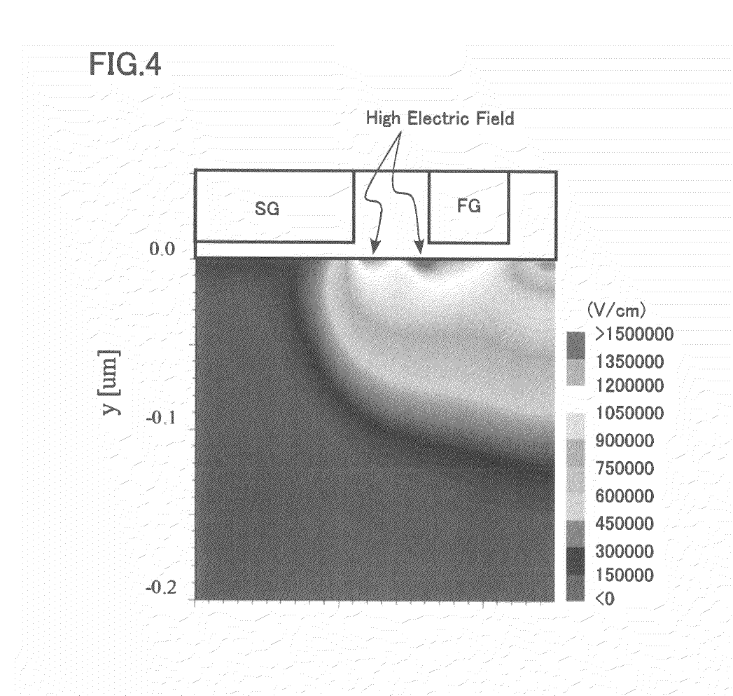

FIG. 4 is a diagram showing a simulation result of an electric field distribution between the memory cell transistor 0 of the non-selected string and a select gate transistor adjacent to the memory cell transistor 0. It can be seen that a high electric field is generated between the memory cell transistor 0 (portion FG in FIG. 4) and the select gate transistor (portion SG in FIG. 4) adjacent thereto. The simulation is basically performed under the voltage conditions previously illustrated.

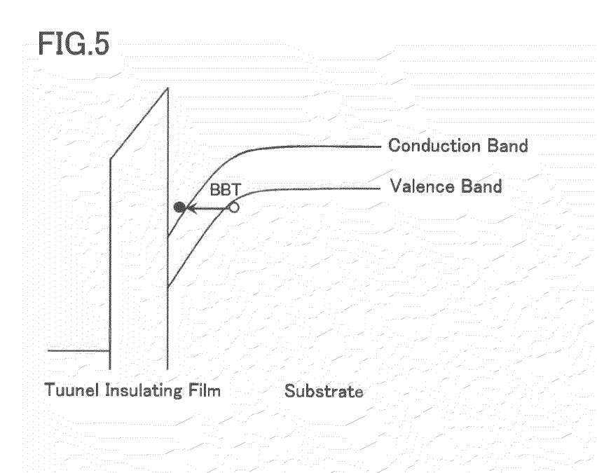

FIG. 5 is a band diagram in the high electric field region. BBT (Band-to-Band-Tunneling) is generated by the high electric field generated as shown in FIG. 5. In this case, the BBT, as schematically shown in FIG. 5, is a phenomenon in which an electron tunnel from a valence band to a conduction band occurs because the conduction band and the valence band are considerably curved due to the high electric field.

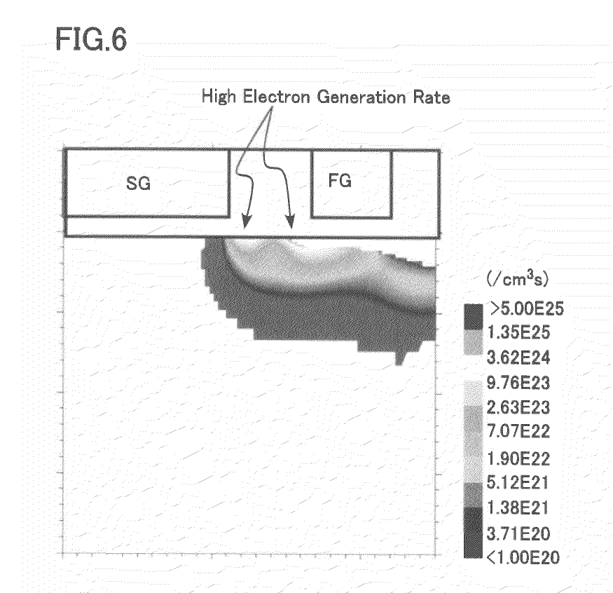

FIG. 6 is a diagram showing a simulation result of a generation rate of electrons due to BBT. It is apparent that a generation rate of electrons is high in the intense electric field region in FIG. 4.

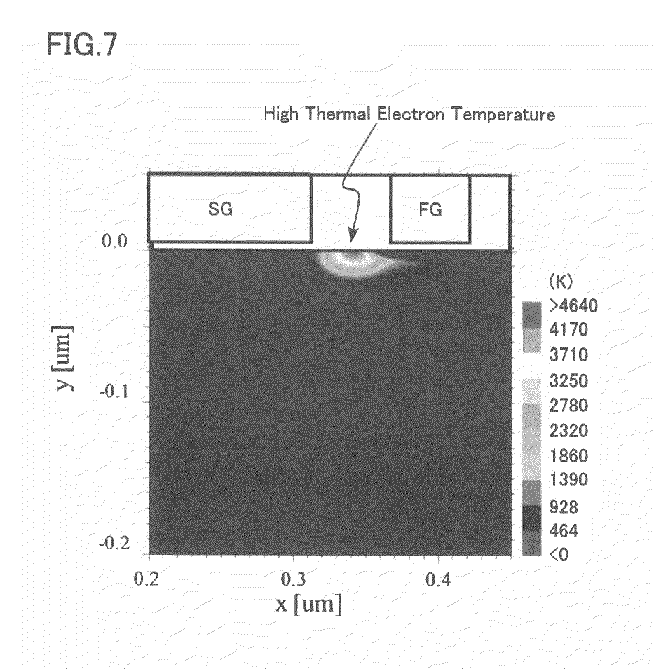

FIG. 7 is a diagram showing a simulation result of an electron temperature distribution of thermal electrons. Electrons generated due to BBT are accelerated by the electric field and become thermal electrons. As is apparent from FIG. 7, electrons are accelerated by an electric field and become thermal electrons. The thermal electrons (hot carriers) generated as described above are erroneously written in the memory cell transistor 0 to cause miss-operation.

In this manner, the write error due to thermal electron considerably depends on an electric field between the select gate transistor and the memory cell transistor. This electric field is determined depending on a diffusion layer profile between the select gate transistor and the memory cell transistor. Therefore, the write error due to thermal electron consequently considerably depends on a diffusion layer profile between the select gate transistor and the memory cell transistor.

Diffusion layer profile dependence of write error characteristics is an essence of the effect of the embodiment. Therefore, a result obtained by studying the dependence and a mechanism thereof by simulation will be described below.

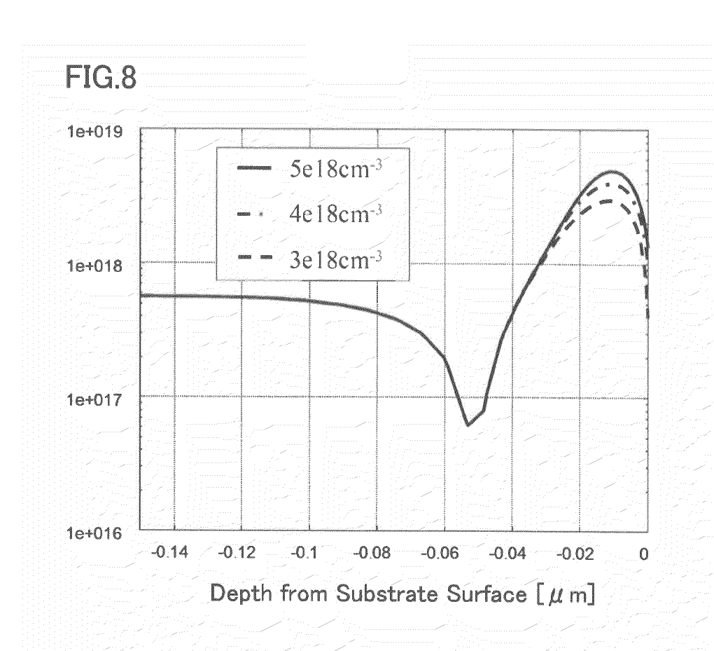

FIG. 8 is a diagram showing a distribution of As (arsenic), considered in the simulation, in a depth direction near the center between the select gate transistor and the memory cell transistor 0.

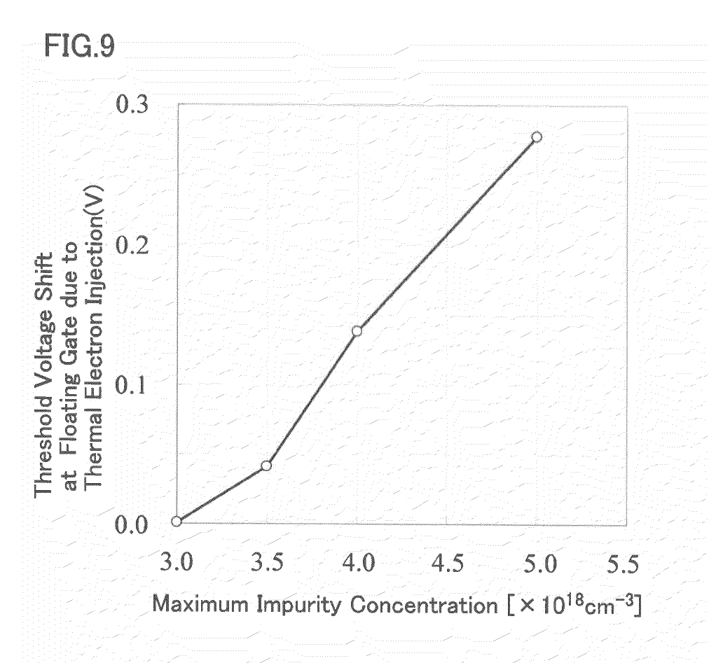

FIG. 9 is a graph showing dependence of a threshold voltage shift on maximum impurity concentration of a diffusion layer. A threshold voltage shift at the floating gate caused by write error due to thermal electrons injection into the floating gate (charge storage layer) of the memory cell transistor 0 has a dependence on maximum impurity concentration of a diffusion layer as shown in FIG. 9.

More specifically, when a diffusion layer concentration between the select gate transistor and the memory cell transistor is high, electrons erroneously written in the memory cell transistor 0 increase. This can be understood from a potential distribution and an electric field distribution between the select gate transistor and the memory cell transistor.

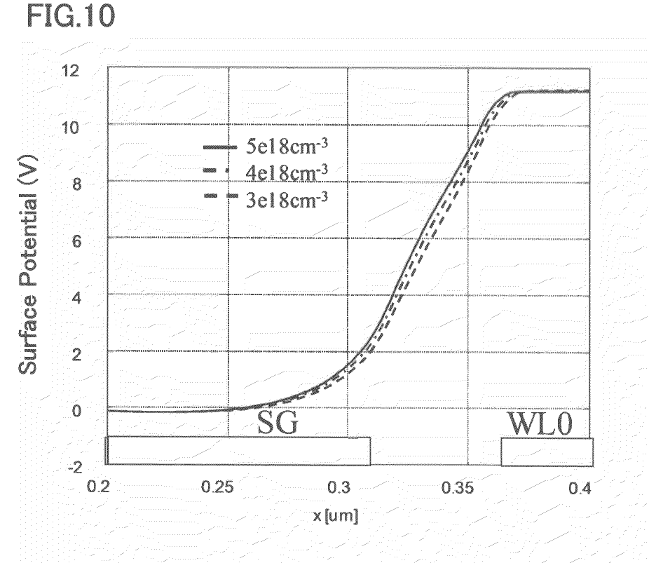

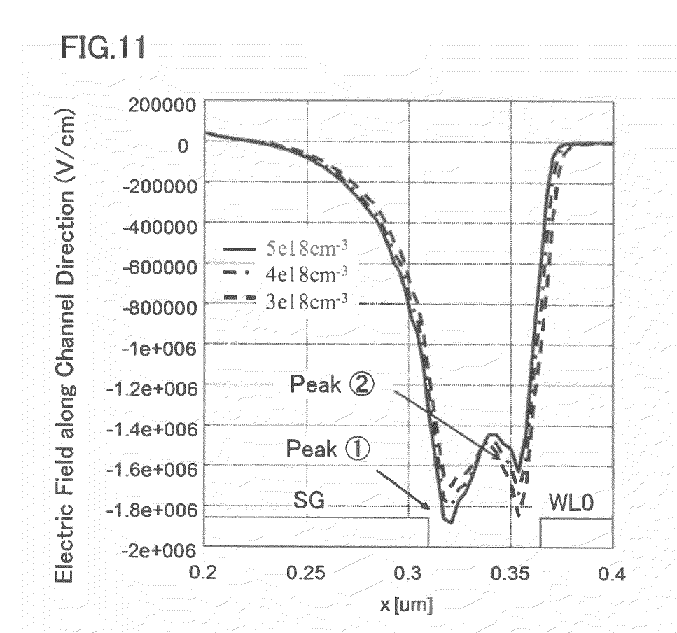

FIG. 10 is a graph showing a surface potential distribution between a select gate and the memory cell transistor 0. FIG. 11 is a graph showing a channel-direction electric field distribution.

As is apparent from FIG. 10, when the maximum impurity concentration of a diffusion layer is high, a potential shifts from the memory cell transistor 0 (WL0 in FIG. 10) to the select gate transistor (SG in FIG. 10). This is because a diffusion layer resistance is in inverse proportion to the maximum impurity concentration.

As a result, as shown in FIG. 11, a peak position of the channel-direction electric field distribution gets close to the select gate transistor (Peak \textcircled{1}) when the maximum impurity concentration of the diffusion layer increases. When the maximum impurity concentration of the diffusion layer is low, the peak of the channel-direction electric field is present near the end of the memory cell transistor 0 (peak 2 in FIG. 11). For this reason, BBT occurs in this region.

At for a peak 2, since a region in which BBT occurs is adjacent to a channel portion of the memory cell transistor 0, electrons generated due to the BBT are stored in the channel of the memory cell transistor 0 without time to accelerate the electrons. As a result, when the impurity concentration of the diffusion layer is low, as shown in FIG. 9, write error due to thermal electrons decrease. In this manner, the dependence of the write error due to thermal electron on the diffusion layer impurity profile can be understood from the behavior of the electric field shown in FIG. 11.

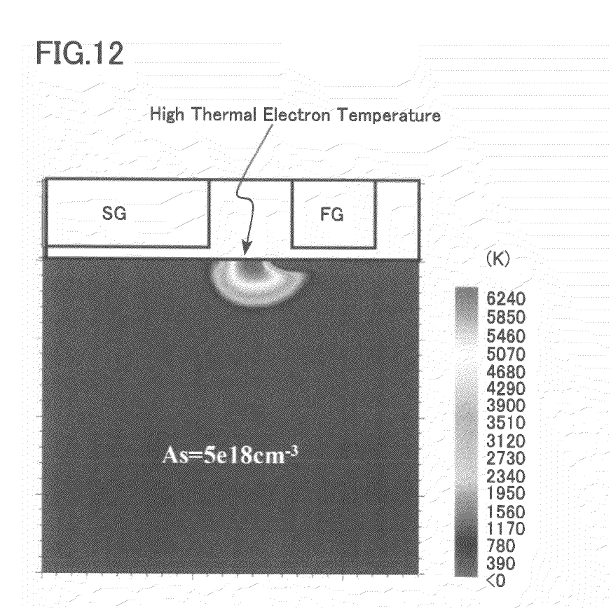

FIG. 12 is a diagram showing an electric field distribution obtained when a maximum impurity concentration of the diffusion layer is 5e18 cm⁻³. FIG. 13 is a diagram showing an electric field distribution obtained when the maximum impurity concentration of the diffusion layer is 3e18 cm⁻³.

As shown in FIG. 12, when the maximum impurity concentration of the diffusion layer is high, electrons generated due to the BBT are accelerated and easily become thermal electrons. In contrast, when the maximum impurity concentration of the diffusion layer is low, as shown in FIG. 13, an electron temperature does not easily rise. As described above, in order to suppress thermal electron from being generated, electric field concentration at an end of the select gate transistor is preferably lowered.

A characteristics of the present embodiment is, as described above, that an impurity profile of the diffusion layer (impurity layer) of the memory cell transistor MT00 in the NAND string shown in FIG. 1A has an offset structure in which a concentration at an end of the select gate transistor is low as shown in FIG. 1B. The asymmetrical diffusion layer impurity profile can suppress thermal electrons from being erroneously written.

The mechanism will be described below with reference to the drawings. FIG. 14 is a graph showing comparison of a diffusion layer impurity profile and a surface potential distribution. In FIG. 14, a surface potential distribution obtained when a symmetrical diffusion layer impurity profile of a conventional technique (reference) is used is compared with a surface potential distribution obtained when the diffusion layer impurity profile according to the embodiment is used.

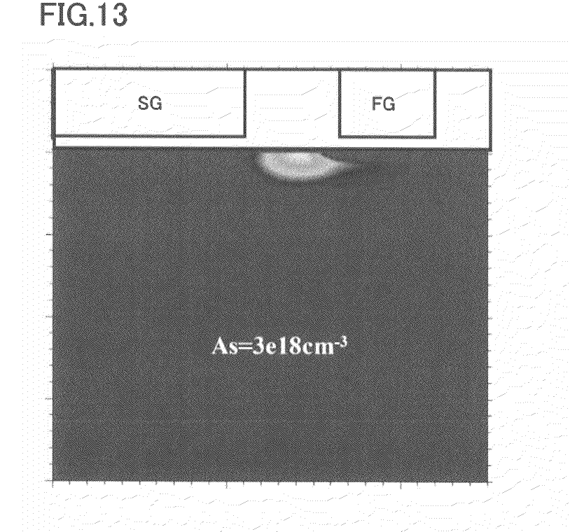

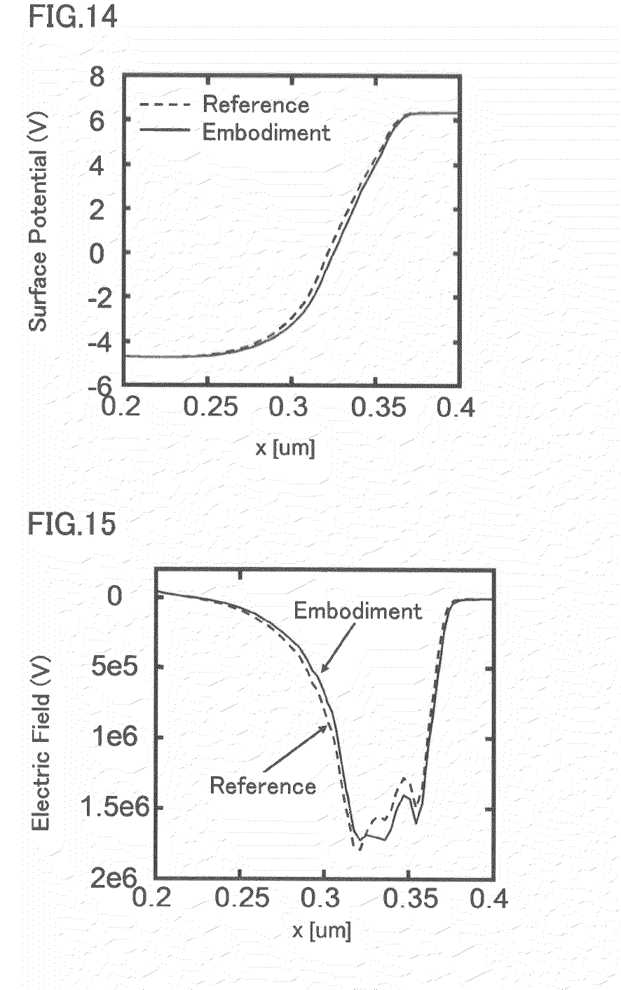

FIG. 15 is a graph showing comparison of the diffusion layer impurity profile and a channel electric field. As in FIG. 15, an electric field obtained when the symmetrical diffusion layer impurity profile of the conventional technique (reference) is used is compared with an electric field obtained when the diffusion layer impurity profile according to the embodiment is used.

As is apparent from FIG. 14, when the diffusion impurity profile according to the embodiment is used, a surface potential more largely shifts to the memory cell transistor 0 side (right side in FIG. 14). As a result, as shown in FIG. 15, when the diffusion layer impurity profile according to the embodiment is used, electric field concentration at the end of the select gate lowers. Consequently, a temperature of the thermal electrons decreases.

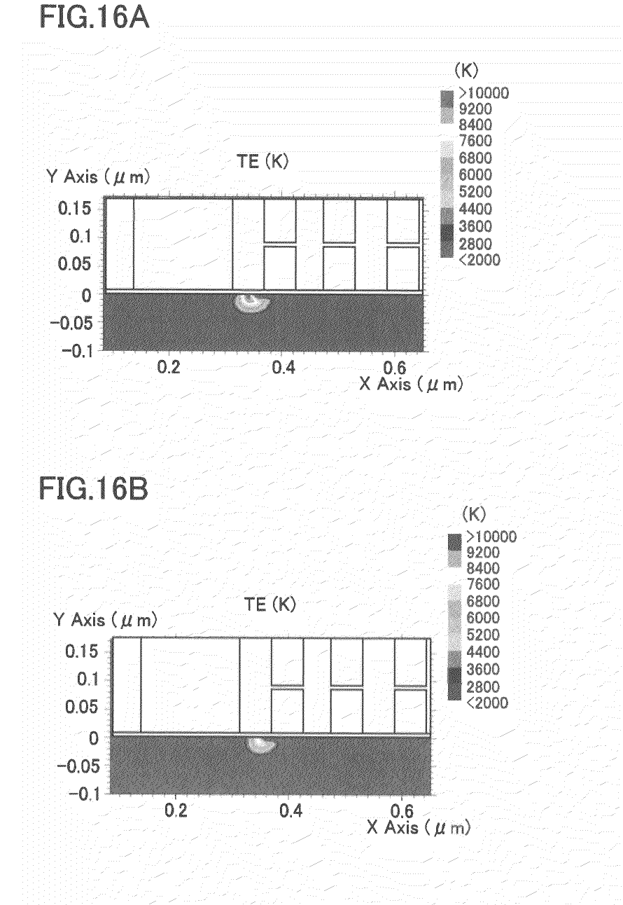

FIGS. 16A and 16B are comparative diagrams of temperature distributions of thermal electrons. FIG. 16A is a thermal electron temperature distribution obtained when the diffusion layer impurity profile of the conventional technique (reference) is used. FIG. 16B is a thermal electron temperature distribution obtained when the diffusion layer impurity profile according to the embodiment is used. As is apparent from FIG. 16, when the diffusion layer impurity profile according to the embodiment is used, the temperature of the thermal electrons is lower than the reference.

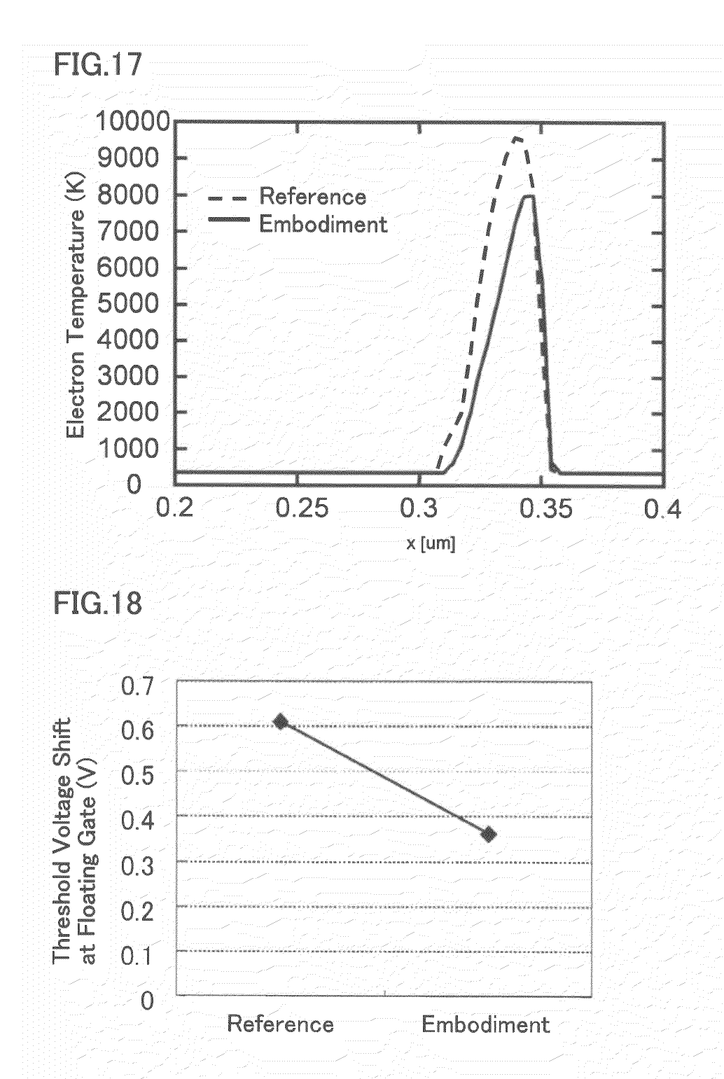

FIG. 17 is a graph showing comparison of a surface electron temperature distribution of thermal electrons. It is apparent that the temperature of the thermal electrons is lower when the diffusion layer impurity profile according to the embodiment is used.

FIG. 18 is a graph showing a write error suppression effect of the embodiment. Since the temperature of the thermal electrons is lowered, as shown in FIG. 18, a threshold voltage shift at the floating gate (FG: Floating Gate) caused by write error due to thermal electron is smaller when the diffusion layer impurity profile according to the embodiment is used. Therefore, the thermal electrons are suppressed from being erroneously written.

As described above, according to the semiconductor memory device of the embodiment, an offset structure in which a concentration is low at the end of the select gate is given to the diffusion layer impurity profile of the memory cell transistor 0, thereby suppressing the thermal electrons from being erroneously written.

Write error in the memory cell transistor MT00 (FIG. 1) connected to the select gate transistor STS on the source side is mainly described here. This is because an electric field on the source side is more intense than that on the drain side. Although it is not always necessary on the drain side, an asymmetrical impurity layer is desirably formed also on the drain side as in the nonvolatile semiconductor memory device according to the embodiment shown in FIG. 1A, because the similar erroneous writing may occur on the drain side.

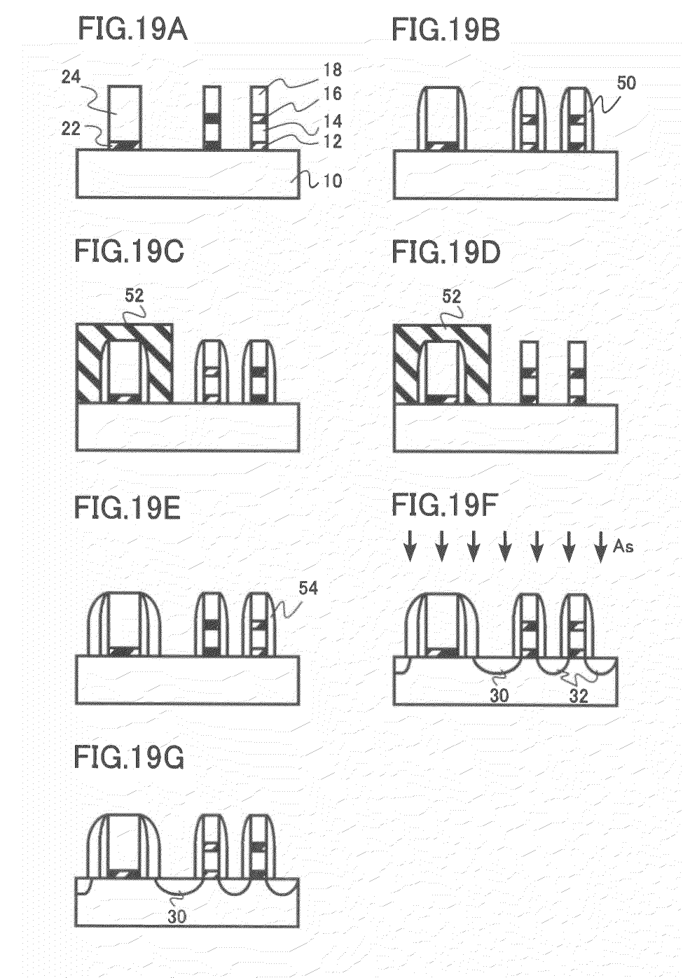

An example of a method of manufacturing a nonvolatile semiconductor memory device according to the embodiment will be described below. FIGS. 19A to 19G are sectional views showing steps of the method of manufacturing the nonvolatile semiconductor memory device according to the embodiment.

For example, on the p-type semiconductor substrate 10, materials for the first insulating film 12 and the third insulating film 22 are deposited. Next, materials for the charge storage layer 14 and a part of the select gate electrode 24 are deposited. Thereafter, a material for the second insulating film 16 is deposited, and the second insulating film 16 is removed from only a region serving as the select gate electrode 24. Materials for the control gate electrode 18 and a part of the select gate electrode 24 are deposited. Thereafter, these stacked structures are patterned to form a structure shown in FIG. 19A. In this embodiment, an electrical connection at the select gate electrode 24 between the charge storage layer 14 material and the control gate electrode 18 material is achieved by selectively removing the second insulating film 16 before the deposition of the control gate electrode 18 material. Instead, the electrical connection may also be achieved by forming a contact electrode penetrating through both the control gate electrode 18 material and the second insulating film 16 after the deposition of the control gate electrode 18 material.

Next, a first side wall insulating film 50 is formed by deposition and anisotropic etching of a film to obtain a structure shown in FIG. 19B. Only a select gate transistor portion is masked by a resist film 52 (FIG. 19C). Only the first side wall insulating film 50 of the memory cell transistor portion is removed by wet etching (FIG. 19D).

After the resist film 52 is removed, a second side wall insulating film 54 is formed by deposition and anisotropic etching of films performed again to obtain a structure in FIG. 19E. Thereafter, for example, As is implanted into the semiconductor substrate 10 by ion implantation to form the diffusion layers 30 and 32 (FIG. 19F). Finally, as shown in FIG. 19G, a nonvolatile semiconductor memory device, in which the diffusion layer (first impurity layer) 30 between the select gate transistor and the memory cell transistor connected thereto has an offset structure, is formed.

### Second Embodiment

A nonvolatile semiconductor memory device according to a second embodiment is characterized in that a depth of a first impurity layer is larger on a memory cell transistor side of a first virtual plane than on a select gate transistor side. Other than this point, the present embodiment is the same as the first embodiment. Therefore, the duplicated contents with the first embodiment are not described.

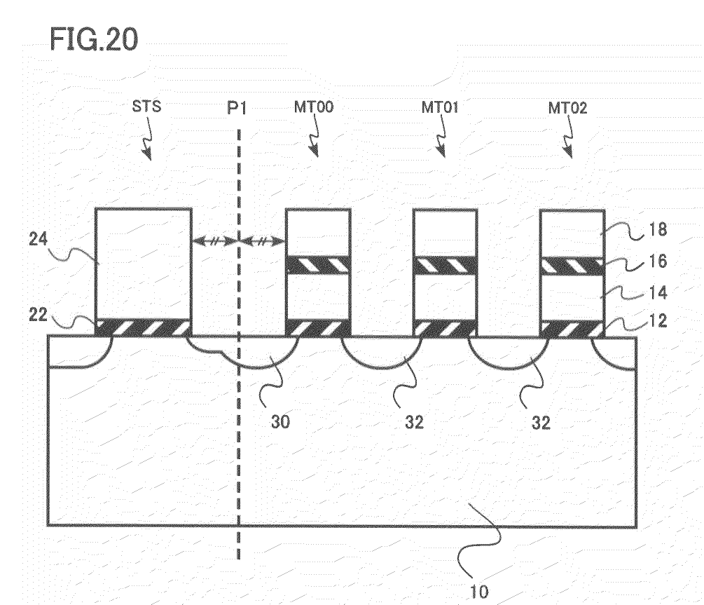

FIG. 20 is a sectional view of a main part of the nonvolatile semiconductor memory device according to the embodiment. As shown in FIG. 20, a depth of the first impurity layer 30 is larger on the memory cell transistor MT00 side of the first virtual plane P1 than on the select gate transistor STS side.

In this manner, also in the embodiment, as in the first embodiment, the first impurity layer 30 is asymmetrical and has a high concentration on the memory cell transistor MT00 side. Therefore, the same write error suppressing effect as that of the first embodiment is obtained. Contrary to the first embodiment, the first impurity layer is not offset with reference to the select gate electrode 24. Therefore, risk of an increase in ON resistance of the select gate transistor STS caused by an offset can be advantageously reduced.

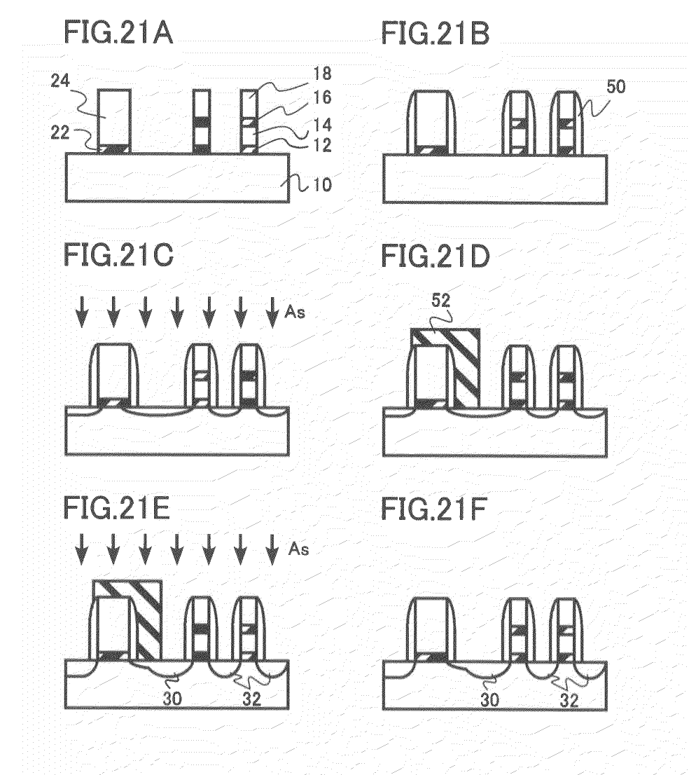

Next, an example of the method of manufacturing a nonvolatile semiconductor memory device according to the embodiment will be described. FIGS. 21A to 21F are sectional views showing steps of a method of manufacturing the nonvolatile semiconductor memory device according to the embodiment.

For example, on the p-type semiconductor substrate 10, materials for the first insulating film 12 and the third insulating film 22 are deposited. Next, materials for the charge storage layer 14 and a part of the select gate electrode 24 are deposited. Thereafter, a material for the second insulating film 16 is deposited, and the second insulating film 16 is removed from only a region serving as the select gate electrode 24. Materials for the control gate electrode 18 and a part of the select gate electrode 24 are deposited. Thereafter, these stacked structures are patterned to form a structure shown in FIG. 21A. In this embodiment, an electrical connection at the select gate electrode 24 between the charge storage layer 14 material and the control gate electrode 18 material is achieved by selectively removing the second insulating film 16 before the deposition of the control gate electrode 18 material. Instead, the electrical connection may also be achieved by forming a contact electrode penetrating through both the control gate electrode 18 material and the second insulating film 16 after the deposition of the control gate electrode 18 material.

Next, the first side wall insulating film 50 is formed by deposition and anisotropic etching of a film to obtain a structure shown in FIG. 21B. Thereafter, for example, As is implanted into the semiconductor substrate 10 by ion implantation to form shallow diffusion layers (FIG. 21C).

Then, only the memory cell transistor side of the select gate transistor portion is masked by the resist film 52 (FIG. 21D). Thereafter, for example, As is implanted into the semiconductor substrate 10 by ion implantation performed by using the resist film 52 as a mask to form the diffusion layers 30 and 32 which are deeper than the diffusion layers described above (FIG. 21E).

The resist film 52 is removed to form a nonvolatile semiconductor memory device in which the depth of the first impurity layer 30 is larger on the memory cell transistor MT00 side of the first virtual plane P1 than on the select gate transistor STS side (FIG. 21F).

### Third Embodiment

A nonvolatile semiconductor memory device according to a third embodiment of the present invention includes on a main plane of a semiconductor substrate: a plurality of memory cell transistors connected in series with each other, dummy cell transistors connected to ends of the plurality of memory cell transistors, and select gate transistors connected to the dummy cell transistors. Each of the memory cell transistors includes a first insulating film on the semiconductor substrate, a first charge storage layer on the first insulating film, a second insulating film on the first charge storage layer, and a control gate electrode on the second insulating film. Each of the select gate transistors includes a third insulating film on the semiconductor substrate, and a select gate electrode on the third insulating film. Each of the dummy cell transistors includes a fourth insulating film on the semiconductor substrate, a second charge storage layer on the fourth insulating film, a fifth insulating film on the second charge storage layer, and a dummy gate electrode on the fifth insulating film. A first impurity layer of a conductivity type opposite to the conductivity type of the semiconductor substrate is formed as a common source/drain on the semiconductor substrate between each of the select gate transistors and a dummy cell transistor connected to the select gate transistor. An impurity concentration distribution of the first impurity layer is asymmetrical with respect to a first virtual plane being at equal distances from ends of the select gate electrode and the dummy gate electrode and being perpendicular to the main plane of the semiconductor substrate, and an impurity concentration of the first impurity layer on the dummy cell transistor side is higher than that on the select gate transistor side with reference to the first virtual plane.

The nonvolatile semiconductor memory device according to the embodiment have dummy cell transistors. And the memory device suppress degradation in characteristic of the nonvolatile semiconductor memory device caused by write error due to hot carrier injection occurred in the charge storage layer of the dummy cell transistor. A physical structure of a NAND string is the same as that of the first embodiment. Each of the transistors connected to the select gate transistors does not function as a memory cell transistor but a dummy cell transistor. Other than this point, the present embodiment is the same as the first embodiment. Therefore, the duplicated contents with the first embodiment are not described.

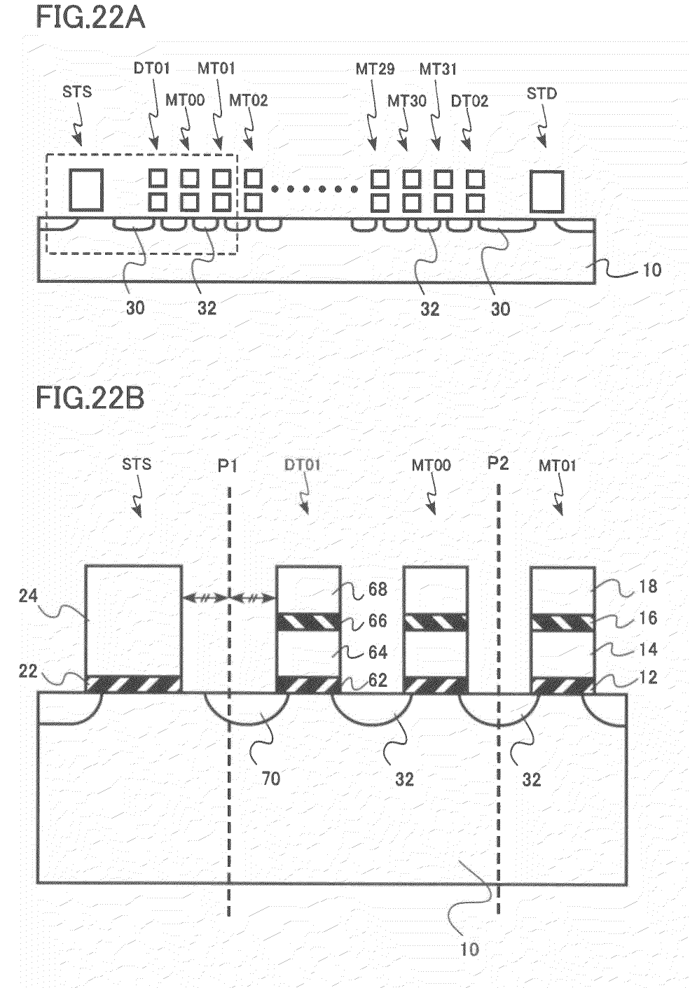

FIGS. 22A and 22B are sectional views of a nonvolatile semiconductor memory device according to the embodiment. FIG. 22A is an entire diagram, and FIG. 22B is an enlarged diagram of a main part indicated by a broken-line rectangle in FIG. 22A.

As shown in FIG. 22A, the nonvolatile semiconductor memory device according to the embodiment includes the plurality of memory cell transistors MT00 to MT31 connected in series with each other on the semiconductor substrate 10. Dummy cell transistors DT01 and DT02 are connected to ends of the memory cell transistors MT00 to MT31. Furthermore, the select gate transistors STS and STD are connected to the dummy cell transistors DT01 and DT02.

The nonvolatile semiconductor memory device according to the embodiment is different from that of the first embodiment in that a NAND string has the dummy cell transistors DT01 and DT02. At an end of a memory cell array at which periodicity of a layout pattern is broken, a variation in characteristic easily occurs due to defective pattern formation of a memory cell transistor caused by a process. The dummy cell transistors DT01 and DT02 are provided to avoid the problem.

The memory cell transistor includes the first insulating film 12 on the semiconductor substrate 10, the charge storage layer 14 on the first insulating film 12, the second insulating film 16 on the first charge storage layer 14, and the control gate electrode 18 on the second insulating film 16.

Each of the dummy cell transistors DT01 and DT02, as shown in FIG. 22B, includes a fourth insulating film 62 on the semiconductor substrate 10, a second charge storage layer 64 on the fourth insulating film, a fifth insulating film 66 on the second charge storage layer 64, and a dummy gate electrode 68 on the fifth insulating film 66.

The fourth insulating film 62 is made of, for example, a silicon oxide film. The second charge storage layer 64 is made of, for example, polysilicon. The fifth insulating film 66 is made of, for example, alumina. The dummy gate electrode 68 has a stacked structure of, for example, polysilicon and tantalum nitride. These materials and layer structures are the same as those of the memory cell transistors MT00 to MT31.

The second charge storage layer 64 does not have a feature of positively storing electric charges as memory cell information. However, as in the memory cell transistor, when thermal electrons are written, threshold voltages of the dummy cell transistors DT01 and DT02 vary. In this case, ON currents of the dummy cell transistors DT01 and DT02 vary to be in a risk of causing miss-operation of the nonvolatile semiconductor memory device.

A first impurity layer 70 of a conductivity type opposite to that of the semiconductor substrate 10 is formed as a common source/drain on the semiconductor substrate 10 between the select gate transistor STS and the dummy cell transistor DT01 connected to the select gate transistor STS. An impurity concentration distribution of the first impurity layer 70 is asymmetrical with respect to a first virtual plane P1 being at equal distances from ends of the select gate electrode 24 and the dummy gate electrode 68 and being perpendicular to the main plane of the semiconductor substrate. Further, an impurity concentration of the first impurity layer 70 on the dummy cell transistor DT01 side is higher than that on the select gate transistor STS side with reference to the first virtual plane P1.

Also in the embodiment, as in the first embodiment, the first impurity layer 70 is offset with reference to the select gate electrode 24 to obtain an asymmetrical concentration distribution.

Also in the embodiment, according to the above configuration, the same function as that in the first embodiment prevents write error in the second charge storage layer 64 of the dummy cell transistor DT01. Therefore, miss-operation of the nonvolatile semiconductor memory device caused by a variation in threshold voltage of the dummy cell transistor DT01 can be suppressed.

As in the second embodiment, it is also advantageous that a depth of the first impurity layer 70 is made larger on the dummy cell transistor DT01 side than on the select gate transistor STS side with reference to the first virtual plane P1. In this manner, miss-operation can be suppressed, and risk of an increase in ON resistance of the select gate transistor STS caused by an offset can be advantageously reduced.

As in the first embodiment, the impurity concentration distribution of the second impurity layer 32 in FIG. 22 is desirably symmetrical with respect to the second virtual plane P2 being at equal distances from the ends of the control gate electrodes 18 of the two memory cell transistors and being perpendicular to the main plane of the semiconductor substrate 10.

### Fourth Embodiment

A nonvolatile semiconductor memory device according to a fourth embodiment of the present invention includes on a main plane of a semiconductor substrate: a plurality of memory cell transistors connected in series with each other and select gate transistors connected to ends of the plurality of memory cell transistors. Each of the memory cell transistors includes a first insulating film on the semiconductor substrate, a charge storage layer on the first insulating film, a second insulating film on the charge storage layer, and a control gate electrode on the second insulating layer. Each of the select gate transistors includes a third insulating film on the semiconductor substrate, and a select gate electrode on the third insulating film. A conductive layer containing a metal is formed as a common source/drain on the semiconductor substrate between each of the select gate transistors and a memory cell transistor connected to the select gate transistor, and a horizontal distance between the conductive layer and the select gate electrode is larger than a horizontal distance between the conductive layer and the control gate electrode.

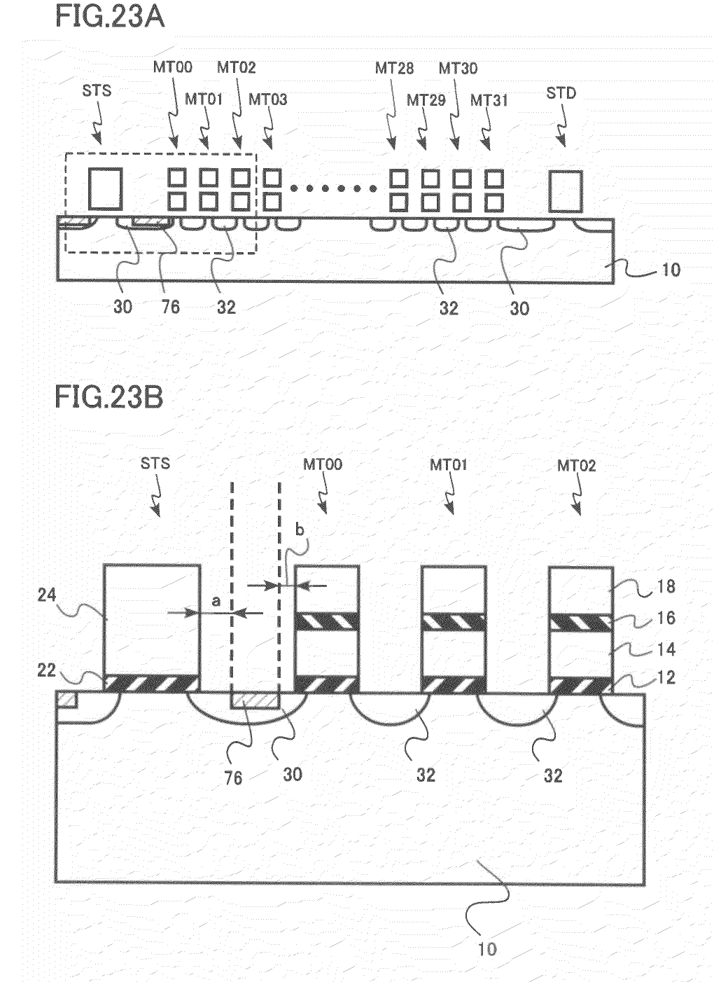

FIGS. 23A and 23B are sectional views of a nonvolatile semiconductor memory device according to the embodiment. FIG. 23A is an entire diagram, and FIG. 23B is an enlarged diagram of a main part indicated by a broken-line rectangle in FIG. 23A.

In the embodiment, a conductive layer 76 containing a metal is formed as a common source/drain on the semiconductor substrate between the select gate transistor STS and the memory cell transistor MT00 connected to the select gate transistor STS. The conductive layer 76 containing a metal may be made of only a metal, an alloy, or a metal-semiconductor compound.

A horizontal distance “a” between the conductive layer 76 and the select gate electrode 24 is larger than a horizontal distance “b” between the conductive layer 76 and the control gate electrode 18. The first impurity layer 30 is not asymmetrical unlike in the first embodiment. Except for the two points, the embodiment is the same as the first embodiment. In the embodiment, although the first impurity layer 30 is not always necessary to be formed, the first impurity layer 30 is desirably formed in terms of a reduction in junction leakage of a transistor, a reduction in parasitic resistance, and the like.

Also in the embodiment, the conductive layer 76 is shifted toward the memory cell transistor MT00 side to suppress thermal electrons from being generated. Therefore, a nonvolatile semiconductor memory device, which suppresses write error and has improved reliability, can be provided.

A configuration, in which a conductive layer made of the same material as that of the conductive layer 76 is formed on the semiconductor substrate between memory cell array transistors, may be employed. In this case, horizontal distances between the conductive layer and the two control gate electrodes of the adjacent memory cell transistors are desirably equal to each other to make the characteristics of the memory cell transistors symmetrical.

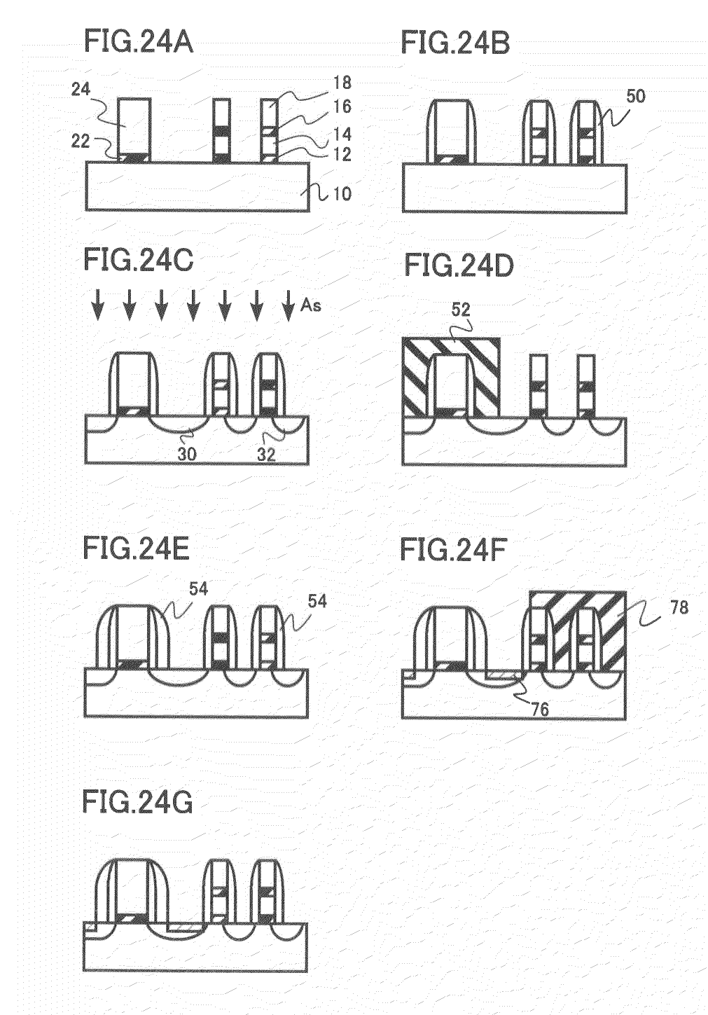

A method of manufacturing a nonvolatile semiconductor memory device according to the embodiment will be described below. FIGS. 24A to 24G are sectional views showing steps of a method of manufacturing the nonvolatile semiconductor memory device according to the embodiment.

For example, materials for the first insulating film 12, the charge storage layer 14, the second insulating film 16, and the control gate electrode 18 are sequentially stacked on the p-type semiconductor substrate 10. Materials for the third insulating film 22 and the select gate electrode 24 are sequentially stacked on the semiconductor substrate 10. Thereafter, these stacked structures are patterned to form a structure shown in FIG. 24A.

Next, the first side wall insulating film 50 is formed by deposition and anisotropic etching of a film to obtain a structure shown in FIG. 24B. Then, As is implanted into the semiconductor substrate 10 by ion implantation to form the diffusion layers 30 and 32 (FIG. 24C).

Next, only the select gate transistor portion is masked by the resist film 52. Then, only the first side wall insulating film 50 of the memory cell transistor portion is removed by wet etching (FIG. 24D).

After the resist film 52 is removed, the second side wall insulating film 54 is formed by deposition and anisotropic etching of films performed again to obtain a structure in FIG. 24E. Thereafter, the memory cell transistor is selectively masked by a TEOS film 78 or the like, and, for example, a metal film made of Ni is deposited. Thereafter, anneal is performed to cause the metal film to react with the semiconductor substrate 10 so as to form the conductive layer 76 made of a metal-semiconductor compound. An unreacted metal film is removed by wet etching (FIG. 24F).

The TEOS film 78 is removed. Finally, as shown in FIG. 24G, a nonvolatile semiconductor memory device having a structure in which the conductive layer 76 between the select gate transistor and the memory cell transistor connected thereto is shifted toward the memory cell transistor side is formed.

### Fifth Embodiment

A nonvolatile semiconductor memory device according to a fifth embodiment of the present invention is obtained by applying a conductive layer according to the fourth embodiment to a nonvolatile semiconductor memory device including a dummy cell transistor.

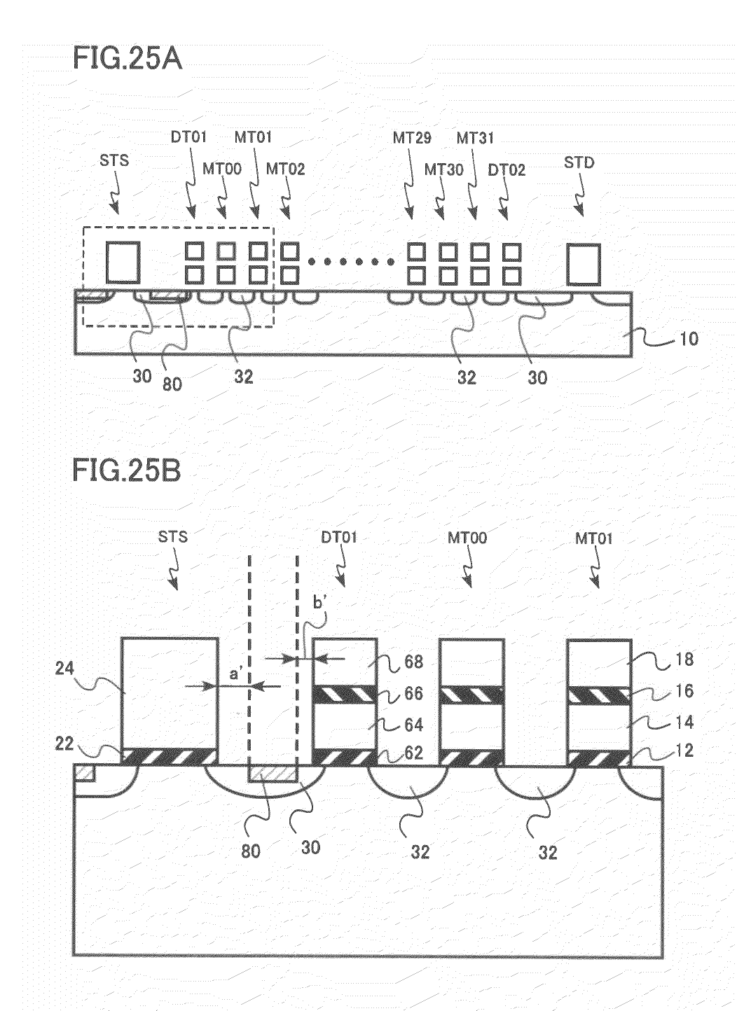

FIGS. 25A and 25B are sectional views of a nonvolatile semiconductor memory device according to the embodiment. FIG. 25A is an entire diagram, and FIG. 25B is an enlarged diagram of a main part indicated by a broken-line rectangle in FIG. 25A.

As shown in FIG. 25A, the semiconductor memory device according to the embodiment includes a plurality of memory cell transistors MT00 to MT31 connected in series with each other on the semiconductor substrate 10. The dummy cell transistors DT01 and DT02 are connected to ends of the plurality of memory cell transistors MT00 to MT31. Furthermore, the select gate transistors STS and STD are connected to the dummy cell transistors DT01 and DT02. These stacked structures are the same as those in the third embodiment.

A conductive layer 80 containing a metal is formed as a common source/drain on the semiconductor substrate 10 between the select gate transistor STS and the dummy cell transistor DT01 connected to the select gate transistor STS. A horizontal distance “a′” between the conductive layer 80 and the select gate electrode 24 is larger than a horizontal distance “b′” between the conductive layer 80 and the dummy gate electrode 68.

Also in the embodiment, according to the above configuration, the same function as that in the fourth embodiment prevents erroneous writing in the second charge storage layer 64 of the dummy cell transistor DT01, and miss-operation of the nonvolatile semiconductor memory device caused by a variation in threshold voltage of the dummy cell transistor DT01 can be suppressed.

### Sixth Embodiment

A nonvolatile semiconductor memory device according to a sixth embodiment of the present invention is the same as that in the first embodiment except that a memory cell transistor has a so-called MONOS (Metal-Oxide-Nitride-Oxide-Semiconductor) structure.

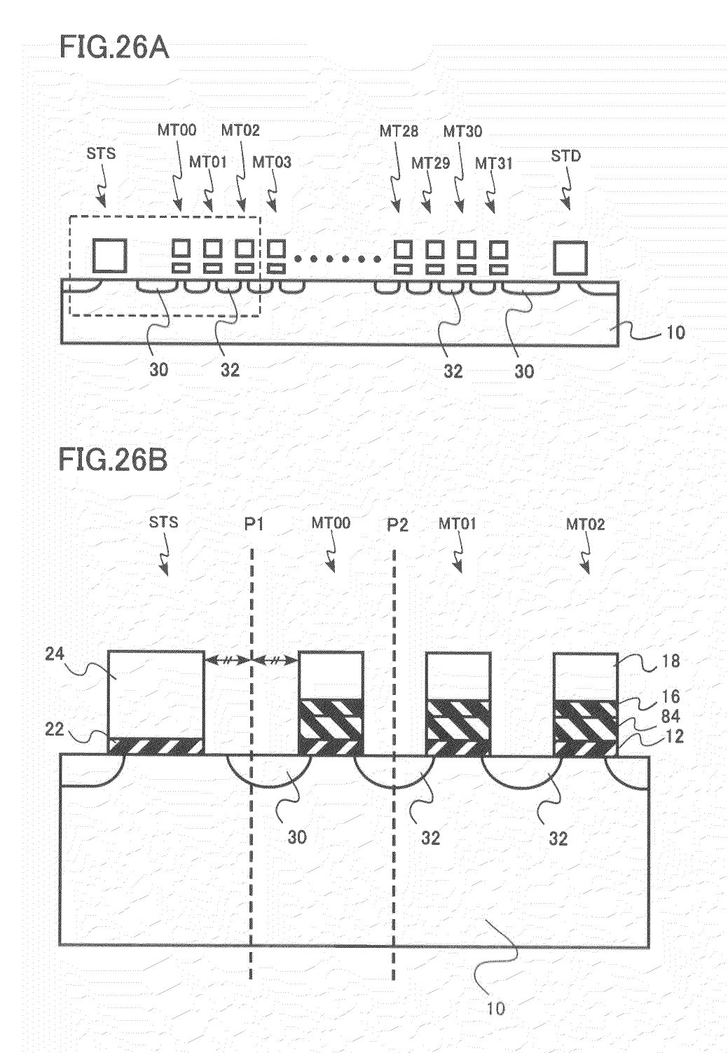

FIGS. 26A and 26B are sectional views of the nonvolatile semiconductor memory device according to the embodiment. FIG. 26A is an entire diagram, and FIG. 26B is an enlarged diagram of a main part indicated by a broken-line rectangle in FIG. 26A.

Each of the memory cell transistors MT00 to MT31, as shown in FIG. 26B, includes the first insulating film 12 on the semiconductor substrate 10, a charge storage layer 84 on the first insulating film 12, the second insulating film 16 on the charge storage layer 84, and the control gate electrode 18 on the second insulating film 16. The first insulating film 12 is formed of, for example, a silicon oxide film. The charge storage layer 84 is an insulating film, and is formed of, for example, a silicon nitride film. The second insulating film is made of, for example, alumina. The control gate electrode 18 has a stacked structure of, for example, polysilicon and tantalum nitride.

Also in the embodiment, as in the first embodiment, a nonvolatile semiconductor memory device which suppresses write error in the charge storage layer 84 to improve the reliability can be advantageously realized. Furthermore, according to a MONOS structure, the embodiment has an advantage that scaling down in a film direction is relatively easily performed, an advantage that reliability is further improved because of suppression of leakage to a channel region, or the like.

Although the embodiments of the present invention are described above, the present invention is not limited to the embodiments, and the present invention can be variously changed within the spirit and scope of the invention described in the scope of claims. The present invention can be variously modified without departing from the spirit and scope of the invention in the execution phase. Furthermore, a plurality of constituent elements disclosed in the embodiments are arbitrarily combined to each other so as to form various embodiments.

What is claimed is:

1. A nonvolatile semiconductor memory device comprising:
a semiconductor substrate;
a plurality of memory cell transistors placed in series with each other formed on a plain of the semiconductor substrate, each of the memory cell transistors includes
a first insulating film on the semiconductor substrate,
a charge storage layer on the first insulating film,
a second insulating film on the charge storage layer, and
a control gate electrode on the second insulating film; and
a select gate transistor placed an end of the plurality of memory cell transistors, the select gate transistor includes
a third insulating film on the semiconductor substrate, and
a select gate electrode on the third insulating film,
wherein
a first impurity layer of a conductivity type opposite to the conductivity type of the semiconductor substrate is formed as a common source/drain on the semiconductor substrate between the select gate transistor and the memory cell transistor next to the select gate transistor,
an impurity concentration distribution of the first impurity layer is asymmetrical with respect to a first virtual plane being at equal distances from ends of the select gate electrode and the control gate electrode and being perpendicular to the plane, and an impurity concentration of the first impurity layer on the memory cell transistor side is higher than that on the select gate electrode side.

2. The device according to claim 1, wherein
a second impurity layer of a conductivity type opposite to the conductivity type of the semiconductor substrate is formed as a common source/drain on the semiconductor substrate between two of the memory cell transistors placed with each other, and
an impurity concentration distribution of the second impurity layer is symmetrical with respect to a second virtual plane being at equal distances from the ends of the control gate electrodes of the two memory cell transistors and being perpendicular to the plane.

3. The device according to claim 1, wherein
the first impurity layer has an offset spacing with respect to the select gate electrode.

4. The device according to claim 1, wherein
a depth of the first impurity layer is larger on the memory cell transistor side than on the select gate transistor side.

5. A nonvolatile semiconductor memory device comprising:
a semiconductor substrate;
a plurality of memory cell transistors placed in series with each other formed on a plain of the semiconductor substrate, each of the memory cell transistors includes
a first insulating film on the semiconductor substrate,
a first charge storage layer on the first insulating film,
a second insulating film on the first charge storage layer,
and
a control gate electrode on the second insulating film;
a dummy cell transistor placed an end of the plurality of memory cell transistors, the dummy cell transistor includes
a fourth insulating film on the semiconductor substrate,
a second charge storage layer on the fourth insulating film,
a fifth insulating film on the second charge storage layer,
and
a dummy gate electrode on the fifth insulating film; and
a select gate transistor placed next to the dummy cell transistor, the select gate transistor includes
a third insulating film on the semiconductor substrate,
and
a select gate electrode on the third insulating film,
wherein
a first impurity layer of a conductivity type opposite to the conductivity type of the semiconductor substrate is formed as a common source/drain on the semiconductor substrate between the select gate transistor and the dummy cell transistor next to the select gate transistor,
an impurity concentration distribution of the first impurity layer is asymmetrical with respect to a first virtual plane being at equal distances from ends of the select gate electrode and the dummy gate electrode and being perpendicular to the plane, and an impurity concentration of the first impurity layer on the dummy cell transistor side is higher than that on the select gate electrode side.

6. The device according to claim 5, wherein
a second impurity layer of a conductivity type opposite to the conductivity type of the semiconductor substrate is formed as a common source/drain on the semiconductor substrate between two of the memory cell transistors connected with each other, and
an impurity concentration distribution of the second impurity layer is symmetrical with respect to a second virtual plane being at equal distances from the ends of the control gate electrodes of the two memory cell transistors and being perpendicular to the main plane.

7. The device according to claim 5, wherein
the first impurity layer has an offset spacing with respect to the select gate electrode.

8. The device according to claim 5, wherein
a depth of the first impurity layer is larger on the dummy cell transistor side than on the select gate transistor side with reference to the first virtual plane.

9. A nonvolatile semiconductor memory device comprising:
a semiconductor substrate;
a plurality of memory cell transistors placed in series with each other formed on a plain of the semiconductor substrate, each of the memory cell transistors includes
a first insulating film on the semiconductor substrate,
a charge storage layer on the first insulating film,
a second insulating film on the charge storage layer, and
a control gate electrode on the second insulating film; and
a select gate transistor placed an end of the plurality of memory cell transistors, the select gate transistor includes
a third insulating film on the semiconductor substrate and
a select gate electrode on the third insulating film,
wherein
a conductive layer containing a metal is formed as a common source/drain on the semiconductor substrate between the select gate transistor and the memory cell transistor next to the select gate transistor, and
a horizontal distance between the conductive layer and the select gate electrode is larger than a horizontal distance between the conductive layer and the control gate electrode.

10. A nonvolatile semiconductor memory device comprising:
a semiconductor substrate;
a plurality of memory cell transistors placed in series with each other formed on a plain of the semiconductor substrate, each of the memory cell transistors includes
a first insulating film on the semiconductor substrate,
a first charge storage layer on the first insulating film,
a second insulating film on the first charge storage layer,
and
a control gate electrode on the second insulating film;
a dummy cell transistor placed an end of the plurality of memory cell transistors, the dummy cell transistor includes
a fourth insulating film on the semiconductor substrate,
a second charge storage layer on the fourth insulating film,
a fifth insulating film on the second charge storage layer,
and
a dummy gate electrode on the fifth insulating film;
and
a select gate transistor placed next to the dummy cell transistor, the select gate transistor includes
a third insulating film on the semiconductor substrate,
and
a select gate electrode on the third insulating film,
wherein
a conductive layer containing a metal is formed as a common source/drain on the semiconductor substrate between the select gate transistor and the dummy cell transistor next to the select gate transistor, and
a horizontal distance between the conductive layer and the select gate electrode is larger than a horizontal distance between the conductive layer and the dummy gate electrode.
